(19) United States
(12) Patent Application Publication
(10) Pub. No.: US 2022/0199895 A1
(43) Pub. Date: Jun. 23, 2022

(54) Piezoelectric Element for Untact Haptic and Method for Manufacturing the Same

(71) Applicants: Hyundai Motor Company, Seoul (KR); Kia Corporation, Seoul (KR)

(72) Inventors: Sun Mi Oh, Bucheon-si (KR); Byung Jin Jang, Suwon-si (KR); Kang Sun Lee, Seongnam-si (KR); Sae Ah Kim, Hwaseong-si (KR)

(21) Appl. No.: 17/443,532

(22) Filed: Jul. 27, 2021

(30) Foreign Application Priority Data
Dec. 21, 2020 (KR) 10-2020-0180237

(51) Int. Cl. H01L 41/313; H01L 41/193; H01L 41/25

(52) U.S. Cl. CPC H01L 41/313; G06F 3/016; H01L 41/25; H01L 41/193

(57) ABSTRACT

An embodiment piezoelectric element includes a piezoelectric composite layer including a polymer and a piezoelectric ceramic, a backing layer disposed on a rear surface of the piezoelectric composite layer and configured to limit vibration of the piezoelectric composite layer, and an adhesive layer bonding the piezoelectric composite layer and the backing layer.

### CROSS-REFERENCE TO RELATED APPLICATIONS

This application claims the benefit of Korean Patent Application No. 10-2020-0180237, filed in the Korean Intellectual Property Office on Dec. 21, 2020, which application is hereby incorporated herein by reference.

### TECHNICAL FIELD

The present disclosure relates to a piezoelectric element for implementing an untact haptic and a method of manufacturing the same.

### BACKGROUND

Research has been conducted to apply untact (contactless) haptic technology to a vehicle for receiving feedback on whether a display or a switch in the vehicle is driven by tactile sensation. The untact haptic technology enables tactile sensation at a certain distance without touching a body, and is implemented using a piezoelectric ceramic element. The untact haptic technology is a method of focusing an ultrasonic signal generated by an ultrasonic transducer which implements ultrasonic band characteristics at a point in the air and adjusting a voltage applied to each transducer to amplify an intensity of the ultrasonic signal.

A piezoelectric ceramic element used in the conventional ultrasonic transducer is not flexible and is capable of being applied only to a flat surface, and thus it is difficult to apply the piezoelectric ceramic element to a three-dimensional shape of a vehicle interior design including a curvature. In addition, a conventional ultrasonic transducer is difficult to downsize because the area of the element is determined depending on a resonance frequency and energy to be generated using the piezoelectric ceramic element.

### SUMMARY

Embodiments of the present disclosure can solve problems occurring in the prior art while advantages achieved by the prior art are maintained intact.

An embodiment of the present disclosure provides a piezoelectric element for implementing an untact haptic using a piezoelectric composite material and a method of manufacturing the same.

The technical problems to be solved by embodiments of the present inventive concept are not limited to the aforementioned problems, and any other technical problems not mentioned herein will be clearly understood from the following description by those skilled in the art to which the present disclosure pertains.

According to an embodiment of the present disclosure, a piezoelectric element includes a piezoelectric composite layer formed of a polymer and a piezoelectric ceramic, a backing layer disposed on a rear surface of the piezoelectric composite layer and limiting vibration of the piezoelectric composite layer, and an adhesive layer bonding the piezoelectric composite layer and the backing layer.

The piezoelectric composite layer is manufactured in a composite structure of a 1-3 mode.

As the polymer, urethane, epoxy, or unsaturated polyester resin is used.

The piezoelectric ceramic has a volume of 40 to 50% of a volume of the polymer.

The piezoelectric ceramic has an aspect ratio of 2.5 or more.

The piezoelectric ceramic is prepared to have a cylinder or a square pillar.

The backing layer adjusts resolution and frequency bandwidth of the piezoelectric element.

The backing layer is prepared by mixing epoxy and tungsten powder and curing the mixed epoxy and tungsten powder.

The adhesive layer is an epoxy-based adhesive and is prepared in a form of a film.

According to an embodiment of the present disclosure, a method of manufacturing a piezoelectric element includes forming a piezoelectric composite layer using a polymer and a piezoelectric ceramic, forming a backing layer that limits vibration of the piezoelectric composite layer, and bonding the piezoelectric composite layer and the backing layer.

The forming of the piezoelectric composite layer includes preparing a molded body depending on a shape of the piezoelectric ceramic using PZT powder, sintering the molded body to prepare the piezoelectric ceramic, modifying a surface of the piezoelectric ceramic through silane treatment, and arranging the piezoelectric ceramic, filling the piezoelectric ceramic with a polymer, and curing the piezoelectric ceramic filled with the polymer.

The forming of the backing layer includes mixing epoxy and tungsten powder and curing the mixed epoxy and tungsten powder in a jig having a curvature.

The bonding includes adhering the piezoelectric composite layer and the backing layer using a conductive adhesive.

The conductive adhesive is an epoxy-based adhesive and is manufactured in a form of a film.

As the polymer, urethane, epoxy, or unsaturated polyester resin is used.

### BRIEF DESCRIPTION OF THE DRAWINGS

The above and other objects, features and advantages of embodiments of the present disclosure will be more apparent from the following detailed description taken in conjunction with the accompanying drawings, in which:

FIG. 1 is a structural diagram illustrating a piezoelectric element according to an embodiment of the present disclosure;

FIG. 2 is a flowchart illustrating a method of manufacturing a piezoelectric element according to an embodiment of the present disclosure; and

FIG. 3 is an exemplary view illustrating an untact haptic module to which a piezoelectric element according to an embodiment of the present disclosure is applied.

### DETAILED DESCRIPTION OF ILLUSTRATIVE EMBODIMENTS

Hereinafter, some embodiments of the present disclosure will be described in detail with reference to the exemplary drawings. In adding the reference numerals to the components of each drawing, it should be noted that the identical or equivalent component is designated by the identical numeral even when they are displayed on other drawings. Further, in describing the embodiments of the present disclosure, a detailed description of well-known features or functions will be omitted in order not to unnecessarily obscure the gist of the present disclosure.

In describing the components of the embodiments according to the present disclosure, terms such as first, second, “A”, “B”, (a), (b), and the like may be used. These terms are merely intended to distinguish one component from another component, and the terms do not limit the nature, sequence or order of the constituent components. Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Herein, a piezoelectric element for implementing an untact haptic is manufactured using a piezoelectric composite material (piezoelectric composite) having excellent piezoelectric characteristics and low acoustic impedance, and thus a piezoelectric element for an untact haptic having excellent piezoelectric characteristics and improved design of a degree of freedom is provided.

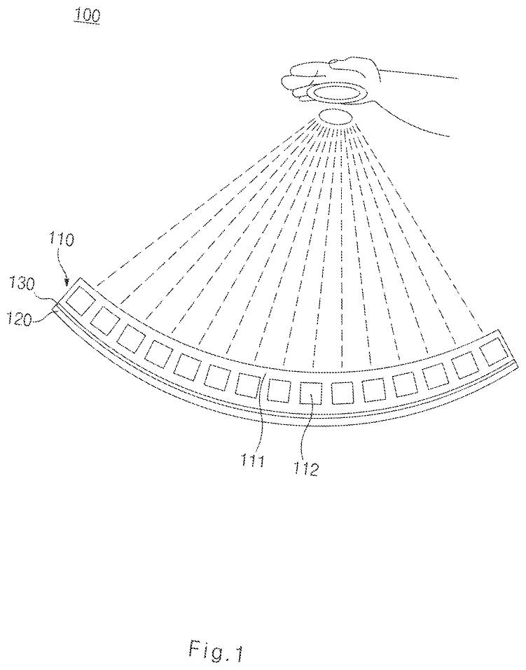

FIG. 1 is a structural diagram illustrating a piezoelectric element according to an embodiment of the present disclosure.

Referring to FIG. 1, a piezoelectric element 100 may include a piezoelectric composite layer no, a backing layer 120, and an adhesive layer 130.

The piezoelectric composite layer no may include a polymer 111 and a piezoelectric ceramic 112. The piezoelectric composite layer no may be composed (formed) of a composite material in which the polymer 111 is used as a matrix and the piezoelectric ceramic 112 is used as an insert material. The piezoelectric composite layer no may be manufactured in a composite structure of a 1-3 mode. The composite structure has various forms depending on shapes or arrangement regularity of the piezoelectric ceramic 112 in the polymer matrix. The composite structure of the 1-3 mode is a structure in which piezoelectric ceramic rods are arranged in the polymer matrix. The composite structure of the 1-3 mode increases efficiency in a longitudinal direction compared to a single-phase piezoelectric ceramic, secures a wide bandwidth, and has a low acoustic impedance thereby excellently matching air and acoustic and having a curved structure.

The polymer 111 should have a low density for securing the low acoustic impedance and a high adhesion to the piezoelectric ceramic 112, and should not generate bubbles therein during a curing process. In addition, a polarization of the polymer 111 proceeds in oil of 100° C., and thus the polymer 111 and the piezoelectric ceramic 112 should be made of a material that does not deteriorate adhesion. Therefore, as the polymer 111, urethane, epoxy, or unsaturated polyester resin may be used.

The piezoelectric ceramic 112 may be manufactured to maintain an aspect ratio of 2.5 or more. The piezoelectric ceramic 112 may be manufactured in a shape such as a cylinder or a square pillar. The piezoelectric ceramic 112 may be manufactured to have a width of 2 mm to 10 mm and a height of 2.5 times or more of the width. A volume of the piezoelectric ceramic 112 may be 40 to 50% of a volume of the polymer 111.

The backing layer 120 may be disposed on a rear surface of the piezoelectric composite layer no and may serve as a damper for limiting vibration of the piezoelectric composite layer no. The backing layer 120 may adjust resolution and frequency bandwidth of the piezoelectric element 100. The backing layer 120 may be prepared by mixing epoxy and tungsten powder and curing the mixed epoxy and tungsten powder in a jig having a curvature. A particle size of the tungsten powder may be 1 μm.

The adhesive layer 130 may couple (adhere) the piezoelectric composite layer no and the backing layer 120 between the piezoelectric composite layer no and the backing layer 120. The adhesive layer 130 may be an epoxy-based adhesive and may be formed in a form of a film.

Although not shown in the drawings, electrodes may be formed on upper and lower surfaces of the piezoelectric composite layer no, and by simultaneously applying power to the corresponding electrodes, an ultrasonic signal generated from the piezoelectric composite layer no may be focused to a point in the air.

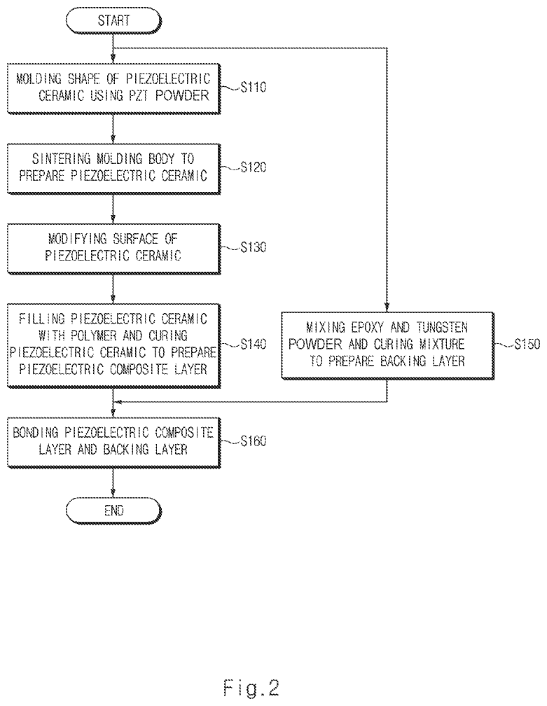

FIG. 2 is a flowchart illustrating a method of manufacturing a piezoelectric element according to an embodiment of the present disclosure.

The piezoelectric element 100 for implementing the untact haptic may be manufactured by forming the piezoelectric composite layer no and the backing layer 120 and bonding the piezoelectric composite layer no to the backing layer 120 using a conductive adhesive.

First, a molding for implementing a shape of the piezoelectric ceramic 112 may be performed using lead zirconate titanate (PZT) powder in S110. Through the molding, a molded body depending on the shape (e.g., a cylinder, etc.) of the piezoelectric ceramic 112 may be manufactured.

The piezoelectric ceramic 112 may be prepared by sintering the molded body manufactured using PZT powder in S120.

A surface of the piezoelectric ceramic 112 may be modified through a silane treatment in S130. The adhesion between the polymer 111 and the piezoelectric ceramic 112 may be improved through surface modification of the piezoelectric ceramic 112.

The piezoelectric ceramic 112 may be arranged, may be filled with the polymer 111, and then may be cured to prepare the piezoelectric composite layer no in S140.

After the epoxy and tungsten powder are blended (mixed) and are cured, the backing layer 120 may be prepared in S150. The particle size of the tungsten powder may be 1 μm. Here, the mixture of epoxy and tungsten powder may be cured in a jig having a curvature.

The piezoelectric composite layer no and the backing layer 120 may be bonded using the conductive adhesive in S160. The adhesive may be an epoxy-based adhesive and may be in a form of a film.

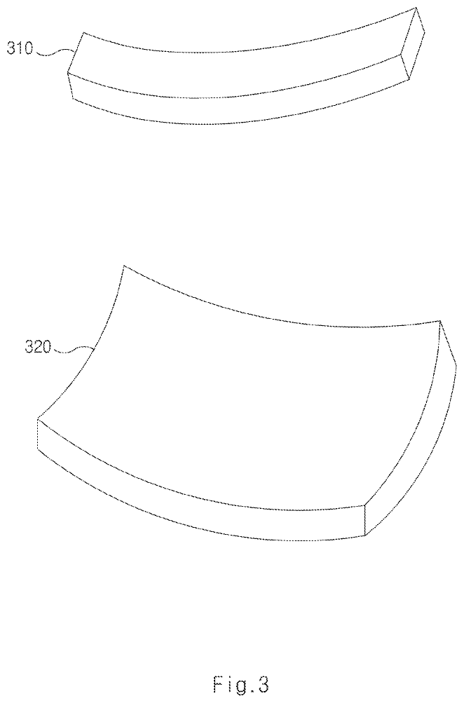

FIG. 3 is an exemplary view illustrating an untact haptic module to which a piezoelectric element according to an embodiment of the present disclosure is applied.

An untact haptic module may use a flexible piezoelectric composite, and thus the piezoelectric ceramics 112 may transmit ultrasonic waves to one point in the air even when voltage is simultaneously applied.

A piezoelectric element may be manufactured using a flexible piezoelectric composite, and thus the backing layer 120 may be prepared in a 1D shape 310 and may be bonded with the piezoelectric composite, thereby manufacturing the untact haptic module having a linear curvature.

In addition, the backing layer 120 may be manufactured in a 2D form 320, thereby manufacturing a 2D haptic module.

As described above, the flexible piezoelectric composite may be used, and thus the untact haptic module having the curvature type desired by a user may be manufactured.

According to embodiments of the present disclosure, the piezoelectric element may be manufactured using the piezoelectric composite material, and thus may be flexible and may be applied to the complex shape and surface.

In addition, according to embodiments of the present disclosure, the piezoelectric element may have a flexible structure, and thus the ultrasonic integration may be improved, thereby miniaturizing the haptic module and minimalizing the signal processing.

In addition, according to embodiments of the present disclosure, the piezoelectric composite material may be applied to implement the high output characteristics and high sensitivity of the haptic, thereby improving the haptic efficiency.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims. Therefore, the exemplary embodiments of the present disclosure are provided to explain the spirit and scope of the present disclosure, but not to limit them, so that the spirit and scope of the present disclosure is not limited by the embodiments. The scope of the present disclosure should be construed on the basis of the accompanying claims, and all the technical ideas within the scope equivalent to the claims should be included in the scope of the present disclosure.

What is claimed is:

1. A piezoelectric element comprising:
a piezoelectric composite layer comprising a polymer and a piezoelectric ceramic;
a backing layer disposed on a rear surface of the piezoelectric composite layer and configured to limit vibration of the piezoelectric composite layer; and
an adhesive layer bonding the piezoelectric composite layer and the backing layer.

2. The piezoelectric element of claim 1, wherein the piezoelectric composite layer has a composite structure of a 1-3 mode.

3. The piezoelectric element of claim 1, wherein the polymer comprises urethane, epoxy, or unsaturated polyester resin.

4. The piezoelectric element of claim 1, wherein the piezoelectric ceramic has a volume of 40 to 50% of a volume of the polymer.

5. The piezoelectric element of claim 1, wherein the piezoelectric ceramic has an aspect ratio of at least 2.5.

6. The piezoelectric element of claim 1, wherein the piezoelectric ceramic is a cylinder or a square pillar.

7. The piezoelectric element of claim 1, wherein the backing layer is configured to adjust a resolution and a frequency bandwidth of the piezoelectric element.

8. The piezoelectric element of claim 1, wherein the backing layer comprises a mix of epoxy and tungsten powder that is cured.

9. The piezoelectric element of claim 1, wherein the adhesive layer is an epoxy-based adhesive in a form of a film.

10. A method of manufacturing a piezoelectric element, the method comprising:
forming a piezoelectric composite layer using a polymer and a piezoelectric ceramic;
forming a backing layer that limits vibration of the piezoelectric composite layer; and
bonding the piezoelectric composite layer and the backing layer.

11. The method of claim 10, wherein forming the piezoelectric composite layer includes:
preparing a molded body depending on a shape of the piezoelectric ceramic using PZT powder;
sintering the molded body to prepare the piezoelectric ceramic;
modifying a surface of the piezoelectric ceramic through a silane treatment; and
arranging the piezoelectric ceramic, filling the piezoelectric ceramic with the polymer, and curing the piezoelectric ceramic filled with the polymer.

12. The method of claim 10, wherein forming the backing layer includes mixing epoxy and tungsten powder and curing the mixed epoxy and tungsten powder in a jig having a curvature.

13. The method of claim 10, wherein bonding the piezoelectric composite layer and the backing layer includes adhering the piezoelectric composite layer and the backing layer using a conductive adhesive.

14. The method of claim 13, wherein the conductive adhesive is an epoxy-based adhesive and is manufactured as a film.

15. The method of claim 10, wherein the polymer comprises urethane, epoxy, or unsaturated polyester resin.

16. The piezoelectric element of claim 10, wherein the piezoelectric ceramic has a volume of 40 to 50% of a volume of the polymer.

17. The method of claim 10, wherein the piezoelectric ceramic has an aspect ratio of at least 2.5.

18. The method of claim 10, wherein the piezoelectric ceramic is a cylinder or a square pillar.

19. The method of claim 10, wherein the backing layer adjusts a resolution and a frequency bandwidth of the piezoelectric element.

20. A method of manufacturing a piezoelectric element, the method comprising:
forming a piezoelectric composite layer comprising a polymer and a piezoelectric ceramic, wherein forming the piezoelectric composite layer comprises:
preparing a molded body using PZT powder;
sintering the molded body;
modifying a surface of the piezoelectric ceramic through a silane treatment;
filling the piezoelectric ceramic with the polymer; and
curing the piezoelectric ceramic filled with the polymer;
forming a backing layer by mixing epoxy and tungsten powder and curing the mixed epoxy and tungsten powder; and
bonding the piezoelectric composite layer and the backing layer using an epoxy-based adhesive.
